(19) United States
(12) Patent Application Publication
(10) Pub. No.: US 2021/0124253 A1
(43) Pub. Date: Apr. 29, 2021

(54) EXTREME ULTRAVIOLET MASK BLANK DEFECT REDUCTION METHODS

(71) Applicant: Applied Materials, Inc., Santa Clara, CA (US)

(72) Inventors: Herng Yau Yoong, Singapore (SG); Wen Xiao, Singapore (SG); Vibhu Jindal, San Jose, CA (US); Shuwei Liu, Singapore (SG); Sanjay Bhat, Singapore (SG); Azeddine Zerrade, Singapore (SG)

(73) Assignee: Applied Materials, Inc., Santa Clara, CA (US)

(21) Appl. No.: 17/077,170

(22) Filed: Oct. 22, 2020

Related U.S. Application Data
(60) Provisional application No. 62/925,876, filed on Oct. 25, 2019.

(51) Int. Cl. G03F 1/24; G03F 7/16; G03F 1/48

(52) U.S. Cl. CPC G03F 1/24; G03F 1/48; G03F 7/16

(57) ABSTRACT

Extreme ultraviolet (EUV) mask blanks, methods for their manufacture, and production systems therefor are disclosed. A method for forming an EUV mask blank comprises placing a substrate in a multi-cathode physical vapor deposition chamber, depositing a multilayer stack, removing the substrate from the chamber and passivating the PVD chamber.

### CROSS-REFERENCE TO RELATED APPLICATIONS

This application claims priority to U.S. Provisional Application No. 62/925,876, filed Oct. 25, 2019, the entire disclosure of which is hereby incorporated by reference herein.

### TECHNICAL FIELD

The present disclosure relates generally to extreme ultraviolet lithography, and more particularly to extreme ultraviolet mask blank manufacturing methods.

### BACKGROUND

Extreme ultraviolet (EUV) lithography, also known as soft x-ray projection lithography, is used for the manufacture of 0.0135 micron and smaller minimum feature size semiconductor devices. Extreme ultraviolet light, which is generally in the 5 to 100 nanometer wavelength range, is strongly absorbed in virtually all materials. For that reason, extreme ultraviolet systems work by reflection rather than by transmission of light. Through the use of a series of mirrors, or lens elements, and a reflective element, or mask blank, coated with a non-reflective absorber mask pattern, the patterned actinic light is reflected onto a resist-coated semiconductor substrate.

The lens elements and mask blanks of extreme ultraviolet lithography systems are coated with reflective multilayer coatings of materials such as molybdenum and silicon. Reflection values of approximately 65% per lens element, or mask blank, have been obtained by using substrates that are coated with multilayer coatings that strongly reflect light within an extremely narrow ultraviolet bandpass, for example, 12.5 to 14.5 nanometer bandpass for 13.5 nanometer ultraviolet light.

EUV blanks have a low tolerance for defects on the working area of the blank. Silicon and molybdenum deposition leads to unbalanced stress on the chamber, which eventually contributes to stress related defects. The goal is to have zero killer type defects (large defects) in the working area of a blank, as these defects are difficult to repair and have a functioning EUV mask. Thus, there is a need for EUV blanks with reduced defects.

### SUMMARY

One or more embodiments of the disclosure are directed to a method of manufacturing an extreme ultraviolet (EUV) mask blank, the method comprising placing a substrate in a multi-cathode physical vapor deposition (PVD) chamber including a chamber interior, the PVD chamber comprising at least two targets, a first molybdenum target and second molybdenum target; forming a multilayer stack of alternating layers of molybdenum and silicon; removing the substrate from the multi-cathode PVD chamber; and passivating the chamber interior with an active gas to reduce flaking of silicon material from the chamber interior.

Additional embodiments of the disclosure are related to a method of passivating the interior of a multi-cathode physical vapor deposition (PVD) chamber, the method comprising placing a substrate in the multi-cathode physical vapor deposition (PVD) chamber including a chamber interior, the PVD chamber comprising at least two targets, a first molybdenum target and second molybdenum target; forming a multilayer stack of alternating layers of molybdenum and silicon; removing the substrate from the multi-cathode PVD chamber; and passivating the chamber interior by forming a SiOₓ passivation layer on the chamber interior

Further embodiments of the disclosure are directed to a method of passivating the interior of a multi-cathode physical vapor deposition (PVD) chamber, the method comprising placing a substrate in the multi-cathode physical vapor deposition (PVD) chamber including a chamber interior, the PVD chamber comprising at least two targets, a first molybdenum target and second molybdenum target; forming a multilayer stack of alternating layers of molybdenum and silicon; removing the substrate from the multi-cathode PVD chamber; and passivating the chamber interior by forming a SiNₓ passivation layer on the chamber interior.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates an embodiment of an extreme ultraviolet lithography system;

FIG. 2 illustrates an embodiment of an extreme ultraviolet reflective element production system;

FIG. 3 illustrates an embodiment of a multi-cathode physical deposition chamber;

FIG. 4 is a cross-sectional view of a physical vapor deposition apparatus including a physical vapor deposition target according to an embodiment of the disclosure;

FIG. 5 illustrates an embodiment of an extreme ultraviolet reflective element such as an EUV mask blank; and

FIG. 6 is a flowchart showing a process according to one or more embodiments; and

FIGS. 7A-C are graphs showing particle reduction achieved by methods according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “horizontal” as used herein is defined as a plane parallel to the plane or surface of a mask blank, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that reacts with the substrate surface.

Those skilled in the art will understand that the use of ordinals such as “first” and “second” to describe process regions do not imply a specific location within the processing chamber, or order of exposure within the processing chamber.

As used in this specification and the appended claims, the term “substrate” refers to a surface, or portion of a surface, upon which a process acts. It will also be understood by those skilled in the art that reference to a substrate is to only a portion of the substrate, unless the context clearly indicates otherwise. Additionally, in some embodiments, reference to depositing on a substrate means both a bare substrate and a substrate with one or more films or features deposited or formed thereon.

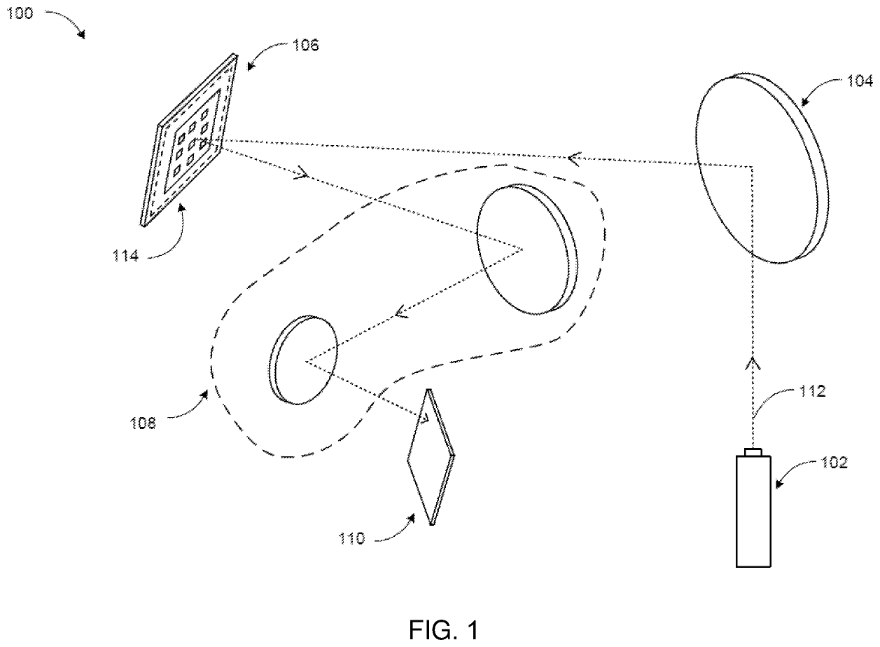

Referring now to FIG. 1, an exemplary embodiment of an extreme ultraviolet lithography system 100 is shown. The extreme ultraviolet lithography system 100 includes an extreme ultraviolet light source 102 for producing extreme ultraviolet light 112, a set of reflective elements, and a target wafer 110. The reflective elements include a condenser 104, an EUV reflective mask 106, an optical reduction assembly 108, a mask blank, a mirror, or a combination thereof.

The extreme ultraviolet light source 102 generates the extreme ultraviolet light 112. The extreme ultraviolet light 112 is electromagnetic radiation having a wavelength in a range of 5 to 50 nanometers (nm). For example, the extreme ultraviolet light source 102 includes a laser, a laser produced plasma, a discharge produced plasma, a free-electron laser, synchrotron radiation, or a combination thereof.

The extreme ultraviolet light source 102 generates the extreme ultraviolet light 112 having a variety of characteristics. The extreme ultraviolet light source 102 produces broadband extreme ultraviolet radiation over a range of wavelengths. For example, the extreme ultraviolet light source 102 generates the extreme ultraviolet light 112 having wavelengths ranging from 5 to 50 nm.

In one or more embodiments, the extreme ultraviolet light source 102 produces the extreme ultraviolet light 112 having a narrow bandwidth. For example, the extreme ultraviolet light source 102 generates the extreme ultraviolet light 112 at 13.5 nm. The center of the wavelength peak is 13.5 nm.

The condenser 104 is an optical unit for reflecting and focusing the extreme ultraviolet light 112. The condenser 104 reflects and concentrates the extreme ultraviolet light 112 from the extreme ultraviolet light source 102 to illuminate the EUV reflective mask 106.

Although the condenser 104 is shown as a single element, it is understood that the condenser 104 of some embodiments includes one or more reflective elements such as concave mirrors, convex mirrors, flat mirrors, or a combination thereof, for reflecting and concentrating the extreme ultraviolet light 112. For example, the condenser 104 of some embodiments is a single concave mirror or an optical assembly having convex, concave, and flat optical elements.

The EUV reflective mask 106 is an extreme ultraviolet reflective element having a mask pattern 114. The EUV reflective mask 106 creates a lithographic pattern to form a circuitry layout to be formed on the target wafer 110. The EUV reflective mask 106 reflects the extreme ultraviolet light 112. The mask pattern 114 defines a portion of a circuitry layout.

The optical reduction assembly 108 is an optical unit for reducing the image of the mask pattern 114. The reflection of the extreme ultraviolet light 112 from the EUV reflective mask 106 is reduced by the optical reduction assembly 108 and reflected on to the target wafer 110. The optical reduction assembly 108 of some embodiments includes mirrors and other optical elements to reduce the size of the image of the mask pattern 114. For example, the optical reduction assembly 108 of some embodiments includes concave mirrors for reflecting and focusing the extreme ultraviolet light 112.

The optical reduction assembly 108 reduces the size of the image of the mask pattern 114 on the target wafer 110. For example, the mask pattern 114 of some embodiments is imaged at a 4:1 ratio by the optical reduction assembly 108 on the target wafer 110 to form the circuitry represented by the mask pattern 114 on the target wafer 110. The extreme ultraviolet light 112 of some embodiments scans the reflective mask 106 synchronously with the target wafer 110 to form the mask pattern 114 on the target wafer 110.

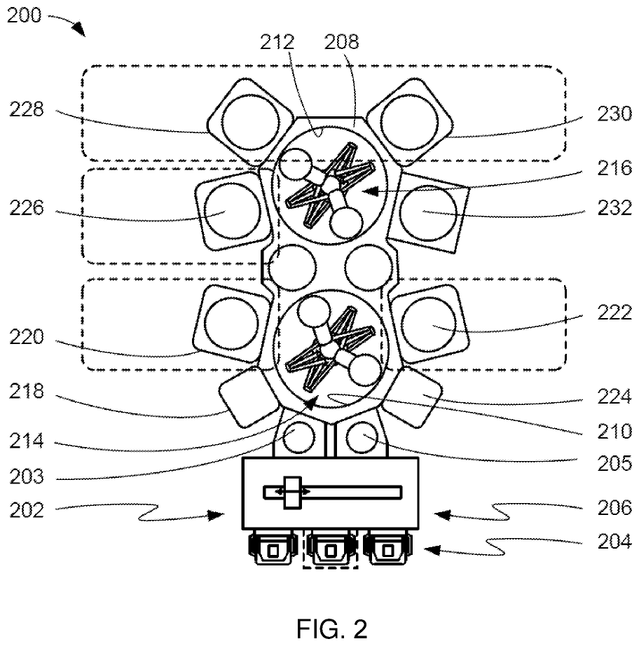

Referring now to FIG. 2, an embodiment of an extreme ultraviolet reflective element production system 200 is shown. The extreme ultraviolet reflective element includes a EUV mask blank 204, an extreme ultraviolet (EUV) mirror 205, or other reflective element such as an EUV reflective mask 106.

The extreme ultraviolet reflective element production system 200 of some embodiments produces mask blanks, mirrors, or other elements that reflect the extreme ultraviolet light 112 of FIG. 1. The extreme ultraviolet reflective element production system 200 fabricates the reflective elements by applying thin coatings to source substrates 203.

The EUV mask blank 204 is a multilayered structure for forming the EUV reflective mask 106 of FIG. 1. The EUV mask blank 204 of some embodiments is formed using semiconductor fabrication techniques. The EUV reflective mask 106 of some embodiments has the mask pattern 114 of FIG. 1 formed on the mask blank 204 by etching and other processes.

The extreme ultraviolet mirror 205 is a multilayered structure reflective in a range of extreme ultraviolet light. The extreme ultraviolet mirror 205 of some embodiments is formed using semiconductor fabrication techniques. The EUV mask blank 204 and the extreme ultraviolet mirror 205 of some embodiments are similar structures with respect to the layers formed on each element, however, the extreme ultraviolet mirror 205 does not have the mask pattern 114.

The reflective elements are efficient reflectors of the extreme ultraviolet light 112. In an embodiment, the EUV mask blank 204 and the extreme ultraviolet mirror 205 has an extreme ultraviolet reflectivity of greater than 60%. The reflective elements are efficient if they reflect more than 60% of the extreme ultraviolet light 112.

The extreme ultraviolet reflective element production system 200 includes a wafer loading and carrier handling system 202 into which the source substrates 203 are loaded and from which the reflective elements are unloaded. An atmospheric handling system 206 provides access to a wafer handling vacuum chamber 208. The wafer loading and carrier handling system 202 of some embodiments includes substrate transport boxes, loadlocks, and other components to transfer a substrate from atmosphere to vacuum inside the system. Because the EUV mask blank 204 is used to form devices at a very small scale, the source substrates 203 and the EUV mask blank 204 are processed in a vacuum system to prevent contamination and other defects.

The wafer handling vacuum chamber 208 of some embodiments contains two vacuum chambers, a first vacuum chamber 210 and a second vacuum chamber 212. The first vacuum chamber 210 includes a first wafer handling system 214 and the second vacuum chamber 212 includes a second wafer handling system 216. Although the wafer handling vacuum chamber 208 is described with two vacuum chambers, it is understood that the system of some embodiments has any number of vacuum chambers.

The wafer handling vacuum chamber 208 of some embodiments has a plurality of ports around its periphery for attachment of various other systems. The first vacuum chamber 210 has a degas system 218, a first physical vapor deposition system 220, a second physical vapor deposition system 222, and a pre-clean system 224. The degas system 218 is for thermally desorbing moisture from the substrates. The pre-clean system 224 is for cleaning the surfaces of the wafers, mask blanks, mirrors, or other optical components.

The physical vapor deposition systems, such as the first physical vapor deposition system 220 and the second physical vapor deposition system 222, of some embodiments are used to form thin films of conductive materials on the source substrates 203. For example, the physical vapor deposition systems of some embodiments include vacuum deposition system such as magnetron sputtering systems, ion sputtering systems, pulsed laser deposition, cathode arc deposition, or a combination thereof. The physical vapor deposition systems, such as the magnetron sputtering system, form thin layers on the source substrates 203 including the layers of silicon, metals, alloys, compounds, or a combination thereof.

The physical vapor deposition system forms reflective layers, capping layers, and absorber layers. For example, the physical vapor deposition systems of some embodiments form layers of silicon, molybdenum, titanium oxide, titanium dioxide, ruthenium oxide, niobium oxide, ruthenium tungsten, ruthenium molybdenum, ruthenium niobium, chromium, tantalum, nitrides, compounds, or a combination thereof. Although some compounds are described as an oxide, it is understood that the compounds of some embodiments include oxides, dioxides, atomic mixtures having oxygen atoms, or a combination thereof.

The second vacuum chamber 212 has a first multi-cathode source 226, a chemical vapor deposition system 228, a cure chamber 230, and an ultra-smooth deposition chamber 232 connected to it. For example, the chemical vapor deposition system 228 of some embodiments includes a flowable chemical vapor deposition system (FCVD), a plasma assisted chemical vapor deposition system (CVD), an aerosol assisted CVD, a hot filament CVD system, or a similar system. In another example, the chemical vapor deposition system 228, the cure chamber 230, and the ultra-smooth deposition chamber 232 of some embodiments are in a separate system from the extreme ultraviolet reflective element production system 200.

The chemical vapor deposition system 228 of some embodiments forms thin films of material on the source substrates 203. For example, the chemical vapor deposition system 228 of some embodiments is used to form layers of materials on the source substrates 203 including mono-crystalline layers, polycrystalline layers, amorphous layers, epitaxial layers, or a combination thereof. The chemical vapor deposition system 228 of some embodiments forms layers of silicon, silicon oxides, silicon oxycarbide, carbon, tungsten, silicon carbide, silicon nitride, titanium nitride, metals, alloys, and other materials suitable for chemical vapor deposition. For example, the chemical vapor deposition system of some embodiments forms planarization layers.

The first wafer handling system 214 is capable of moving the source substrates 203 between the atmospheric handling system 206 and the various systems around the periphery of the first vacuum chamber 210 in a continuous vacuum. The second wafer handling system 216 is capable of moving the source substrates 203 around the second vacuum chamber 212 while maintaining the source substrates 203 in a continuous vacuum. The extreme ultraviolet reflective element production system 200 of some embodiments transfers the source substrates 203 and the EUV mask blank 204 between the first wafer handling system 214, the second wafer handling system 216 in a continuous vacuum.

In the following sections, the term for the EUV mask blank 204 is used interchangeably with the term of the extreme ultraviolet mirror 205 for simplicity. The EUV mask blank 204 is an optically flat structure used for forming the reflective mask 106 having the mask pattern 114. In one or more embodiments, the reflective surface of the EUV mask blank 204 forms a flat focal plane for reflecting the incident light, such as the extreme ultraviolet light 112 of FIG. 1.

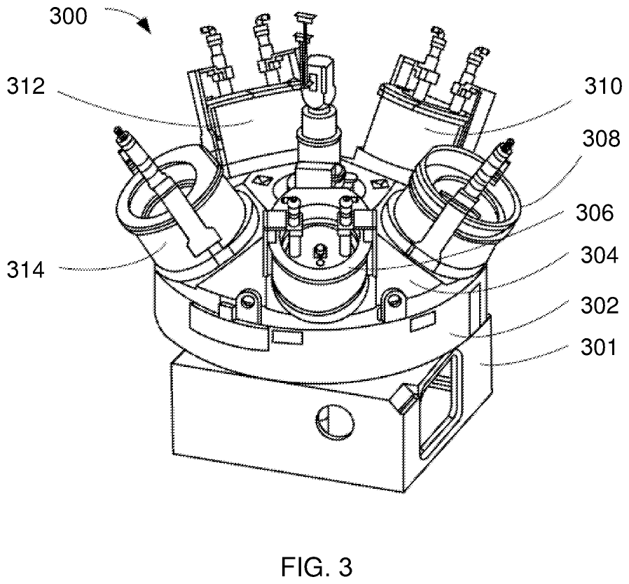

Referring now to FIG. 3, an upper portion of a multi-cathode source chamber 300 is shown in accordance with an embodiment. The first multi-cathode chamber 500 includes a base structure 301 with a cylindrical body portion 302 capped by a top adapter 304. The top adapter 304 has provisions for a number of cathode sources, such as cathode sources 306, 308, 310, 312, and 314, positioned around the top adapter 304.

The multi-cathode source chamber 300 of some embodiments is part of the system shown in FIG. 2. In an embodiment, an extreme ultraviolet (EUV) mask blank production system comprises a substrate handling vacuum chamber for creating a vacuum, a substrate handling platform, in the vacuum, for transporting a substrate loaded in the substrate handling vacuum chamber, a rotating shield having at least one opening for accessing a target, and at least three targets, a first molybdenum target adjacent to a first side of a silicon target and a second molybdenum target adjacent to a second side of the silicon target, for forming an EUV mask blank, including a multilayer stack of reflective layers on the substrate, the multilayer stack including a plurality of reflective layer pairs, and a capping layer on the multilayer stack reflective layers. As used herein, the term “adjacent” refers to the placement of the first molybdenum target immediately next to one side of the silicon target and the second molybdenum target immediately next to the silicon target silicon target on a side opposite the one side.

In some embodiments, the first side of the silicon target and the second side of the silicon target are substantially opposite one another. As used herein, the term “substantially opposite” means that there is a line bisecting the silicon target and the first molybdenum target is on a first end of the bisecting line and the second molybdenum target is on a second end of the bisecting line. The silicon target is therefore bounded on two opposite sides by a molybdenum target.

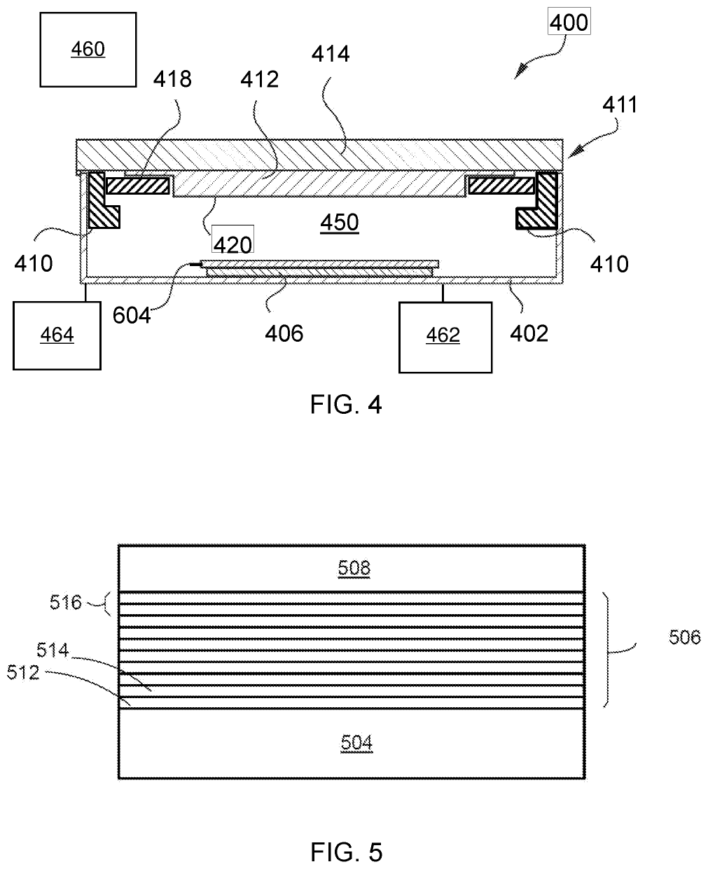

FIG. 4 is a schematic, cross-sectional illustration of a physical vapor deposition apparatus in the form of a physical vapor deposition (PVD) chamber 400 comprising a chamber body 402 and a substrate 404 supported by a substrate support 406 within the chamber body 402 defining a PVD chamber interior 450. The target assembly 411 includes a target 412 supported by a backing plate 414. The target 412 includes a front face 420 or sputterable area disposed in a spaced relationship with respect to the substrate support 406. In some embodiments, the front face 420 of the target 412 is substantially flat.

In some embodiments, the substrate support 406 may be electrically floating or may be biased by a pedestal power supply (not shown). In some embodiments, a process gas is introduced into the chamber 400 via a gas delivery system that typically includes a process gas supply (not shown) including one or more gas sources that feed one or more gas conduits that allow gas to flow into the chamber via a gas inlet that is typically an opening in one of the walls of the chamber. The process gas may comprise a non-reactive gas, such as argon or xenon that energetically impinges upon and sputters material from a target 412. The process gas may also comprise a reactive gas, such as one or more of an oxygen-containing gas and a nitrogen-containing gas, that are capable of reacting with the sputtered material to form a layer on the substrate 404. The target 412 is electrically isolated from the chamber 400 and is connected to a target power supply (not shown), for example, an RF power source, a DC power source, a pulsed DC power source, or a combined power source that uses RF power and/or DC power or pulsed DC power. In one embodiment, the target power source applies negative voltage to the target 412 energizing the process gas to sputter material from the target 412 and onto the substrate 404.

The sputtered material from the target, which is a non-insulator, and in some embodiments is a metal such as molybdenum, or a semiconductor, such as silicon, is deposited on the substrate 404 and forms a solid layer of material. The target assembly 411 includes the backing plate 414 that is joined to the target 412. The back face of the target opposite the front face 420 is joined to the backing plate. It will be appreciated that the target 412 is usually joined to the backing plate by welding, brazing, mechanical fasteners or other suitable joining techniques. The backing plate in some embodiments is fabricated from a high strength, electrically conductive metal in electrical contact with the target. The target backing plate 414 and target 412 may also be formed together as a unitary or integral structure, but typically, they are separate components joined together.

In one or more embodiments, a target shield 418 comprises an insulating material for example, a ceramic material. In some embodiments, a shield support 410 comprises a plurality of openings (not shown) sized to receive fasteners such as bolts or screws to secure the shield support to 410 to the backing plate 414.

Referring now to FIG. 5, an embodiment of an extreme ultraviolet reflective element 502 is shown. In one or more embodiments, the extreme ultraviolet reflective element 502 is the EUV mask blank 204 of FIG. 2 or the extreme ultraviolet mirror 205 of FIG. 2. The EUV mask blank 204 and the extreme ultraviolet mirror 205 are structures for reflecting the extreme ultraviolet light 112 of FIG. 1. The EUV mask blank 204 is used to form the EUV reflective mask 106 shown in FIG. 1.

The extreme ultraviolet reflective element 502 includes a substrate 504, a multilayer stack 506 of reflective layers, and a capping layer 508. In one or more embodiments, the extreme ultraviolet mirror 205 is used to form reflecting structures for use in the condenser 104 of FIG. 1 or the optical reduction assembly 108 of FIG. 1.

The extreme ultraviolet reflective element 502, which in some embodiments is an EUV mask blank 204, includes the substrate 504, the multilayer stack 506 of reflective layers comprising alternating layers of silicon and molybdenum, and an optional capping layer 508. The extreme ultraviolet reflective element 502 in some embodiments is a EUV mask blank 204, which is used to form the reflective mask 106 of FIG. 1 by patterning. In the following sections, the term for the EUV mask blank 204 is used interchangeably with the term of the extreme ultraviolet mirror 205 for simplicity.

The EUV mask blank 204 is an optically flat structure used for forming the reflective mask 106 having the mask pattern 114. In one or more embodiments, the reflective surface of the EUV mask blank 204 forms a flat focal plane for reflecting the incident light, such as the extreme ultraviolet light 112 of FIG. 1.

The substrate 504 is an element for providing structural support to the extreme ultraviolet reflective element 502. In one or more embodiments, the substrate 504 is made from a material having a low coefficient of thermal expansion (CTE) to provide stability during temperature changes. In one or more embodiments, the substrate 504 has properties such as stability against mechanical cycling, thermal cycling, crystal formation, or a combination thereof. The substrate 504 according to one or more embodiments is formed from a material such as silicon, glass, oxides, ceramics, glass ceramics, or a combination thereof.

The multilayer stack 506 is a structure that is reflective to the extreme ultraviolet light 112. The multilayer stack 506 includes alternating reflective layers of a first reflective layer 512 and a second reflective layer 514. The first reflective layer 512 and the second reflective layer 514 form a reflective pair 516 of FIG. 5. In a non-limiting embodiment, the multilayer stack 506 includes a range of 20-60 of the reflective pairs 516 for a total of up to 120 reflective layers.

The first reflective layer 512 and the second reflective layer 514 according to one or more embodiments are formed from a variety of materials. In an embodiment, the first reflective layer 512 and the second reflective layer 514 are formed from silicon and molybdenum, respectively. The first reflective layer 512 and the second reflective layer 514 of some embodiments have a variety of structures. In an embodiment, both the first reflective layer 512 and the second reflective layer 514 are formed with a single layer, multiple layers, a divided layer structure, non-uniform structures, or a combination thereof. Because most materials absorb light at extreme ultraviolet wavelengths, the optical elements used are reflective instead of the transmissive, as used in other lithography systems. The multilayer stack 506 forms a reflective structure by having alternating thin layers of materials with different optical properties to create a Bragg reflector or mirror.

In an embodiment, each of the alternating layers has dissimilar optical constants for the extreme ultraviolet light 112. The alternating layers provide a resonant reflectivity when the period of the thickness of the alternating layers is one half the wavelength of the extreme ultraviolet light 112. In an embodiment, for the extreme ultraviolet light 112 at a wavelength of 13.5 nm, the alternating layers are about 6.5 nm thick. It is understood that the sizes and dimensions provided are within normal engineering tolerances for typical elements.

The multilayer stack 506 according to one or more embodiments is formed in a variety of ways. In an embodiment, the first reflective layer 512 and the second reflective layer 514 are formed with magnetron sputtering, ion sputtering systems, pulsed laser deposition, cathode arc deposition, or a combination thereof.

In an illustrative embodiment, the multilayer stack 506 is formed using a physical vapor deposition technique, such as magnetron sputtering. In an embodiment, the first reflective layer 512 and the second reflective layer 514 of the multilayer stack 506 have the characteristics of being formed by the magnetron sputtering technique including precise thickness, low roughness, and clean interfaces between the layers. In an embodiment, the first reflective layer 512 and the second reflective layer 514 of the multilayer stack 506 have the characteristics of being formed by the physical vapor deposition including precise thickness, low roughness, and clean interfaces between the layers.

The physical dimensions of the layers of the multilayer stack 506 formed using the physical vapor deposition technique are precisely controlled to increase reflectivity. In an embodiment, the first reflective layer 512, such as a layer of silicon, has a thickness of 4.1 nm. The second reflective layer 514, such as a layer of molybdenum, has a thickness of 2.8 nm. The thickness of the layers dictates the peak reflectivity wavelength of the extreme ultraviolet reflective element. If the thickness of the layers is incorrect, the reflectivity at the desired wavelength 13.5 nm of some embodiments reduced.

In one or more embodiments, the capping layer 508 is a protective layer allowing the transmission of the extreme ultraviolet light 112. In an embodiment, the capping layer 508 is formed directly on the multilayer stack 506. In one or more embodiments, the capping layer 508 protects the multilayer stack 506 from contaminants and mechanical damage. In one embodiment, the multilayer stack 506 is sensitive to contamination by oxygen, carbon, hydrocarbons, or a combination thereof. The capping layer 508 according to an embodiment interacts with the contaminants to neutralize them.

Typically, in a multi-cathode (MC) chamber, the target is exposed to the MC chamber through a rotating shield. The shield first moves to a silicon target for deposition, followed by rotating to a molybdenum target. This means that the rotating shield will be exposed to molybdenum or silicon target depositions from the same opening (or hole) in the rotating shield, therefore, providing relatively uniform deposition on the rotating shield compared to the rest of the process kit. The lower process kit (i.e., extension shield, conical shield, cover ring, deposition ring and puck), however, will see non-symmetric deposition. There will be regions, therefore, of the lower process kit that will see pure silicon deposition (silicon-rich areas) and some portions that will see pure molybdenum deposition.

It was discovered that one of the major sources of defects generated during the deposition process during the formation of EUV mask blanks are Si-rich flakes that are flaked off from the process kits in a PVD deposition system due to their poor adhesion to AI/O. A process called “pasting” utilizes deposition of molybdenum to paste down the deposited silicon (i.e. the molybdenum is deposited on top of the silicon and holding the silicon in place), thus preventing the silicon from flaking. It was determined however, that while Mo pasting the process kit after each Si deposition reduces the accumulation of thick Si layers on the process kits, molybdenum pasting could not completely eliminate defects because of the much smaller plasma plume profile of Mo as compared with that of Si prevent Mo from pasting all of the Si deposited areas of the process kit.

In one or more embodiments of the disclosure, a passivation process is introduced in between multilayer deposition to passivate Si-rich regions and increase its adhesion to prevent Si-rich particles from flaking off from portions of the PVD chamber interior 450, for example, process kits, onto the substrate in a PVD chamber. In some embodiments, the passivation process involves the introduction of an active gaseous material, such as O₂ from an O₂ source 462 and N₂ from an N₂ source 464 to into the PVD chamber 400. Flow of the gases in some embodiments is controlled by a mass flow or volume flow controller. According to some embodiments, the active gaseous material reacts with Si either in its molecular state or radical state under a process temperature to form a thin passivation layer on top of Si films.

In some embodiments, use of an external source 460 such as remote plasma source (RPS) or microwave (@13.56 MHz) to further activate the gas to create radicals or ions from the gas molecules are also applied to promote the formation of the passivation layer on the Si layer. In one or more embodiments, passivation process involves a dynamic input of active gas from gas inlets and evacuation via cryogenic or turbo molecular pumps to create a net constant pressure which is kept similar to the process pressure. In some embodiments, the passivation process involves a dynamic input of active gas from gas inlets and evacuation via cryogenic or turbo molecular pumps to create a net constant pressure which is kept similar to the process pressure.

In an exemplary embodiment of a method, after the full deposition of a Mo/Si multilayer stack 506 in the formation of an EUV reflective element 502 as shown in FIG. 5, the top most layer on the PVD chamber interior 450 such as the process kit would be a layer of Si film. The substrate is removed from the process chamber. After the substrate has been removed from chamber, the passivation process conducted. The passivation process would then convert the top few nm of the Si layer into a passivated film. The chamber is then kept idle and pumped down to remove the residual of the passivation gas in the chamber. In some embodiments, all targets are then striked with gas ions to ensure the target surface is cleaned. A new substrate is introduced into the PVD chamber and undergoes a full deposition of Mo/Si multilayer. According to one or more embodiments, the process is conducted in the chambers shown and described in FIGS. 2-4.

In specific embodiments, a passivation gas of O₂ and N₂ and passivation method via using microwave, a remote plasma source RPS or natural passivation are performed after a multilayer stack is formed on a substrate. In some embodiments, a SiOₓ passivation process is performed using a natural oxidation process. For example, O₂ is flowed in a range of 5-30 sccm into the PVD chamber to achieve a PVD chamber pressure in a range of 0.3-3 mTorr. A dwell time in a range of 10-30 mins is used at the multilayer deposition process temperature to induce natural oxidation.

In another embodiment, a downstream plasma assisted oxidation process is used to perform a SiOₓ passivation process. In one embodiment of a downstream plasma assisted oxidation process, O₂ is flowed in a range of 5-30 sccm into the PVD chamber to achieve a PVD chamber pressure in a range of 0.3-3 mTorr for a dwell time in a range of 10-30 mins. Microwave frequency in a range of 1-10 GHz under a power in range of 300-1500 W is applied to create a downstream plasma and promote the oxidation process.

In still another embodiment of a SiOₓ passivation process, plasma enhanced oxidation is used. In an exemplary embodiment of plasma enhanced oxidation, O₂ is flowed in a range of 5-30 sccm into the PVD chamber to achieve a PVD chamber pressure in a range of 0.3-3 mTorr. An external plasma source, such as remote plasma source (RPS) with radio frequency of 13.56 MHz at a power of in a range of 200-1500 W is applied to promote the oxidation process.

In other embodiments, a SiNₓ passivation process is utilized. In one embodiment of a SiNₓ passivation process, natural nitridation is performed by establishing a N₂ flow in a range of 20-40 sccm into a PVD chamber to establish a chamber pressure in a range of 2-5 mTorr for a dwell time in a range of 15-60 mins. This procedure is used at the multilayer deposition process temperature to induce natural nitridation. In another embodiment of a SiNₓ passivation process, a downstream plasma-assisted nitridation process is utilized. In an embodiment of plasma-assisted nitridation process, a N₂ flow in a range of 20-40 sccm is flowed into the PVD chamber to establish a chamber pressure of 2-5 mTorr A microwave frequency in a range of 1-10 GHz at a power in a range of 500-2000 W is applied to create downstream plasma and promote the nitridation process. In still another embodiment of a SiNₓ passivation process, a plasma enhanced nitridation process is used to achieve SiNₓ passivation. In an exemplary embodiment of a plasma enhanced nitridation process, N₂ is flowed into a PVD chamber at a rate in a range of 20-40 sccm at a chamber pressure in a range of 2-5 mTorr. An external plasma source such as remote plasma source (RPS) with radio frequency of 13.56 MHz at a power in a range of 500-2000 W is applied to promote the oxidation process. In some embodiments, after the passivation process is completed, additional metal layers such as aluminum, molybdenum and ruthenium are also deposited onto the process kits to further treat Si-rich regions on the process kits.

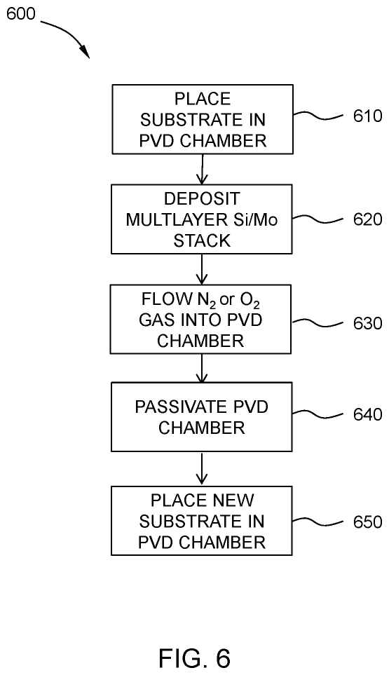

Referring to FIG. 6, in one or more embodiments, a method 600 of manufacturing an extreme ultraviolet (EUV) mask blank comprises placing a substrate in a multi-cathode (MC) physical vapor deposition (PVD) chamber 610. The method 600 further includes depositing a multilayer reflector stack 620, for example a Si/Mo stack. At 630, the substrate is removed from the chamber. The method 600 further includes flowing nitrogen or oxygen gas into the PVD chamber at 640. Then the PVD chamber is passivated at 640 by any of the methods described herein. The method is then repeated according to one or more embodiments.

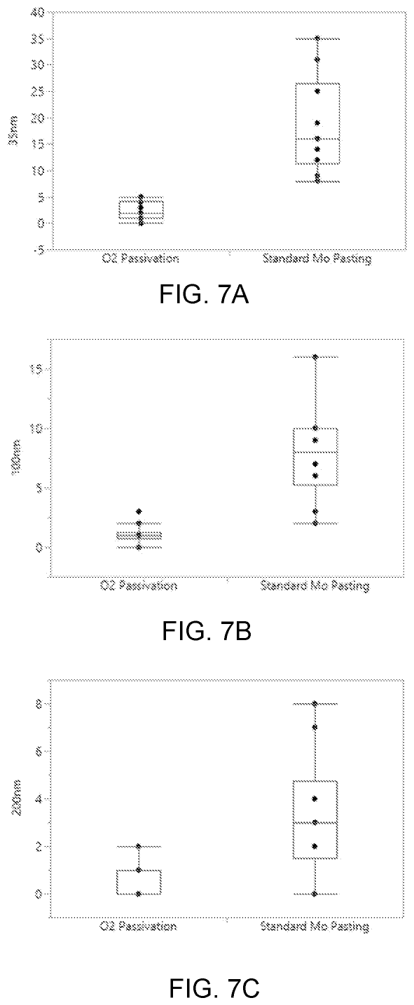

According to one or more embodiments, the passivation process involves the use of a gaseous material, which has better coverage than the standard Mo pasting procedure used in between deposition of multilayer samples to treat Si-rich regions. The passivation process is expected to improve the adhesion of Si films to the PVD chamber interior 450 and reduce the flaking of Si particles. One or more of the passivation processes descried herein provides excellent stress control on the process kits of PVD chambers. In some embodiments, the passivation process results in greatly reduced defect adders (particles), resulting in increase in product yield. Stress control on process kits of PVD chambers extends the lifetime of PVD chamber components. Testing demonstrated a defect reduction compared to molybdenum pasting for 35 nm defects as shown at FIG. 7A, 100 nm defects as shown at FIG. 7B and 200 nm defects as shown at FIG. 7C.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing an extreme ultraviolet (EUV) mask blank, the method comprising:
placing a substrate in a multi-cathode physical vapor deposition (PVD) chamber including a chamber interior, the PVD chamber comprising at least two targets, a first molybdenum target and second molybdenum target;
forming a multilayer stack of alternating layers of molybdenum and silicon;
removing the substrate from the multi-cathode PVD chamber; and
passivating the chamber interior with an active gas to reduce flaking of silicon material from the chamber interior.

2. The method of claim 1, wherein the active gas is selected from oxygen and nitrogen.

3. The method of claim 1, wherein the active gas comprises oxygen.

4. The method of claim 1, wherein the active gas comprises nitrogen.

5. The method of claim 2, further comprising activating the active gas with a remote plasma source to create radicals or ions from the active gas.

6. The method of claim 2, further comprising activating the gas with a microwave source to create radicals or ions from the active gas.

7. The method of claim 6, further comprising controlling pressure in the PVD chamber.

8. The method of claim 6, further comprising flowing the active gas through an inlet and evacuating the gas from the PVD chamber with a pump.

9. A method of passivating an interior of a multi-cathode physical vapor deposition (PVD) chamber, the method comprising:
placing a substrate in the multi-cathode physical vapor deposition (PVD) chamber including a chamber interior, the PVD chamber comprising at least two targets, a first molybdenum target and second molybdenum target;
forming a multilayer stack of alternating layers of molybdenum and silicon;
removing the substrate from the multi-cathode PVD chamber; and
passivating the chamber interior by forming a SiOₓ passivation layer on the chamber interior.

10. The method of claim 9, wherein forming the SiOₓ passivation layer on the chamber interior comprises flowing O₂ in a range of 5-30 sccm into the PVD chamber to achieve a PVD chamber pressure in a range of 0.3-3 mTorr.

11. The method of claim 9, wherein forming the SiOₓ passivation layer on the chamber interior comprises flowing O₂ in a range of 5-30 sccm into the PVD chamber to achieve a PVD chamber pressure in a range of 0.3-3 mTorr and applying a microwave frequency in a range of 1-10 GHz under a power in range of 300-1500 W is applied to create a downstream plasma and form the SiOₓ passivation layer on the chamber interior.

12. The method of claim 11, wherein the microwave frequency is applied for a dwell time in a range of 10-30 mins.

13. The method of claim 9, wherein forming the SiOₓ passivation layer on the chamber interior comprises flowing O₂ in a range of 5-30 sccm into the PVD chamber to achieve a PVD chamber pressure in a range of 0.3-3 mTorr, using a remote plasma source (RPS) to apply a plasma in the chamber with radio frequency of 13.56 MHz at a power in a range of 200-1500 W to form the SiOₓ passivation layer on the chamber interior.

14. The method of claim 13, wherein the plasma is applied for a dwell time in a range of 10-30 mins.

15. A method of passivating an interior of a multi-cathode physical vapor deposition (PVD) chamber, the method comprising:
placing a substrate in the multi-cathode physical vapor deposition (PVD) chamber including a chamber interior, the PVD chamber comprising at least two targets, a first molybdenum target and second molybdenum target;
forming a multilayer stack of alternating layers of molybdenum and silicon;
removing the substrate from the multi-cathode PVD chamber; and
passivating the chamber interior by forming a SiNₓ passivation layer on the chamber interior.

16. The method of claim 15, wherein forming the SiNₓ passivation layer on the chamber interior comprises flowing O₂ in a range of 5-30 sccm into the PVD chamber to achieve a PVD chamber pressure in a range of 0.3-3 mTorr.

17. The method of claim 15, wherein forming the SiNₓ passivation layer on the chamber interior comprises flowing N₂ in a range of 5-30 sccm into the PVD chamber to achieve a PVD chamber pressure in a range of 0.3-3 mTorr and applying a microwave frequency in a range of 1-10 GHz under a power in range of 300-1500 W is applied to create a downstream plasma and form the SiNₓ passivation layer on the chamber interior.

18. The method of claim 17, wherein the microwave frequency is applied for a dwell time in a range of 10-30 mins.

19. The method of claim 9, wherein forming the SiNₓ passivation layer on the chamber interior comprises flowing N₂ in a range of 5-30 sccm into the PVD chamber to achieve a PVD chamber pressure in a range of 0.3-3 mTorr, using a remote plasma source (RPS) to apply a plasma in the chamber with radio frequency of 13.56 MHz at a power in a range of 200-1500 W to form the SiNₓ passivation layer on the chamber interior.

20. The method of claim 14, wherein the plasma is applied for a dwell time in a range of 10-30 mins.
